(19) United States
(12) Patent Application Publication
(10) Pub. No.: US 2011/0248391 A1
(43) Pub. Date: Oct. 13, 2011

(54) INTEGRATED CIRCUIT PACKAGE STACKING SYSTEM WITH LEAD OVERLAP AND METHOD OF MANUFACTURE THEREOF

(76) Inventors: Wei Qiang Jin, Shanghai (CN); Jae Hak Yee, Shanghai (CN); Ya Ping Wang, Shanghai (CN)

(21) Appl. No.: 12/782,164

(22) Filed: May 18, 2010

Related U.S. Application Data
(60) Provisional application No. 61/322,290, filed on Apr. 9, 2010.

(51) Int. Cl. H01L 23/52; H01L 25/065; H01L 21/50

(52) U.S. Cl. 257/676; 438/109; 257/686; 438/123; 257/E21.499; 257/E23.141; 257/E25.013

(57) ABSTRACT

A method of manufacture of an integrated circuit package stacking system includes: providing a bottom package including: providing a first lead frame, forming a bottom package body having the first lead frame in an off-centered parting line position, and forming bottom connection leads of the first lead frame for providing coplanar contacts at an end of the bottom connection leads; mounting a top package on the bottom package including: providing a second lead frame, forming a top package body on the second lead frame, and reforming top connection leads of the second lead frame for over-lapping contact areas on the bottom connection leads of the bottom package; and applying a conductive adhesive on the contact areas for electrically connecting the top connection leads and the bottom connection leads.

### CROSS-REFERENCE TO RELATED APPLICATION

This application claims the benefit of U.S. Provisional Patent Application Ser. No. 61/322,290 filed Apr. 9, 2010, and the subject matter thereof is incorporated herein by reference thereto.

### TECHNICAL FIELD

The present invention relates generally to an integrated circuit package stacking system, and more particularly to a system for stacking packages with leads.

### BACKGROUND ART

Designers of electronic component ranging from portable consumer electronics to massive computer platforms have constantly strived to reduce the size of the systems. The reasons vary from the convenience of carrying one's music library around in one's pocket to limiting the interconnect network in order to reduce the loading so that electrical signals may operate at higher speeds.

Various methods have been employed over the years to reduce the size of systems starting with integrating circuits onto a piece of silicon, then integrating multiple circuits into a single device. However, where multiple instances of a particular device was employed and the size of the die was at the point where no more could be integrated on the die, as is often the case with memory devices, the designers started stacking devices one atop another with an interconnect scheme that electrically connected common signals while isolating and re-routing unique signals.

The state of the art advanced and technologies were then developed that allowed the integration of multiple instances of the silicon die to be integrated into a single package. This provided the designers with components that had multiple instances of the silicon die in a single package without the need for an electrical and mechanical stacking. However, the trend to reduce the size of systems has outpaced the technology of integrating multiple die into a single package. The industry once again finds itself stacking like devices in a system.

The reliability of such stacks of like semiconductor devices has proved to be a problem. While the leads may be in proper alignment they might not make good contact during the stacking process. In order to make a good contact the leads may require reshaping in order to extend toward the lower set of leads.

While reshaped leads on a stacked package may be positioned close to the leads of a base package, there is a high probability that a reliable connection between the two will not be made in an initial attempt. Detection and repair of the faulty connections may cause iterative attempts to reflow the solder that is intended to make the connection. Some of the failures due to lead-free solder reflow cycles are data retention (memory devices), bond wire corrosion and hard failures of the devices. This has caused the manufactures of the semiconductors to specify a maximum number of reflow cycles that the devices experience.

Many stacking technologies used today require multiple reflow cycles to assemble the stacked module. In some cases the number of reflow cycles may exceed the specified maximum for the devices that are being stacked. Then the stacked assemblies have to be attached to modules where they could experience two or more reflow cycles.

Thus, a need still remains for an integrated circuit package stacking system with improved electrical and mechanical coupling of the stacked integrated circuit devices that reduces or eliminates high-temperature reflow cycles from the stack assembly process while providing reliable connections between the packages. In view of the ever-increasing demand for inexpensive higher density solutions, it is increasingly critical that answers be found to these problems. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit package stacking system including: providing a bottom package including: providing a first lead frame, forming a bottom package body having the first lead frame in an off-centered parting line position, and forming bottom connection leads of the first lead frame for providing coplanar contacts at an end of the bottom connection leads; mounting a top package on the bottom package including: providing a second lead frame, forming a top package body on the second lead frame, and reforming top connection leads of the second lead frame for over-lapping contact areas on the bottom connection leads of the bottom package; and applying a conductive adhesive on the contact areas for electrically connecting the top connection leads and the bottom connection leads.

The present invention provides an integrated circuit package stacking system, including: a bottom package includes: a first lead frame, a bottom package body, formed on the first lead frame, having the first lead frame in an off-centered parting line position, and bottom connection leads formed of the first lead frame having coplanar contacts at an end of the bottom connection leads; a top package mounted on the bottom package includes: a second lead frame, a top package body molded on the second lead frame, and top connection leads formed of the second lead frame with contact areas on the bottom connection leads of the bottom package overlapped by the top connection leads; and a conductive adhesive on the contact areas for electrically connecting the top connection leads and the bottom connection leads.

Certain embodiments of the invention have other steps or elements in addition to or in place of those mentioned above. The steps or element will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit package stacking system in a first embodiment of the present invention.

FIG. 2 is a top view of a package-on-package stack utilizing thin small-outline packages (TSOP).

FIG. 3 is a cross-sectional view of an integrated circuit package stacking system in a second embodiment of the present invention.

FIG. 4 is a cross-sectional view of a top package having worst case manufacturing tolerances.

FIG. 5 is a flow chart of a method of manufacture of an integrated circuit package stacking system in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

Where multiple embodiments are disclosed and described having some features in common, for clarity and ease of illustration, description, and comprehension thereof, similar and like features one to another will ordinarily be described with similar reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the integrated circuit package top surface, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures. The term “on” means that there is direct contact between elements with no intervening material.

The term “processing” as used herein includes deposition of material or photoresist, patterning, exposure, development, etching, forming of metal leads, cleaning, and/or removal of the material or photoresist as required in forming a described structure.

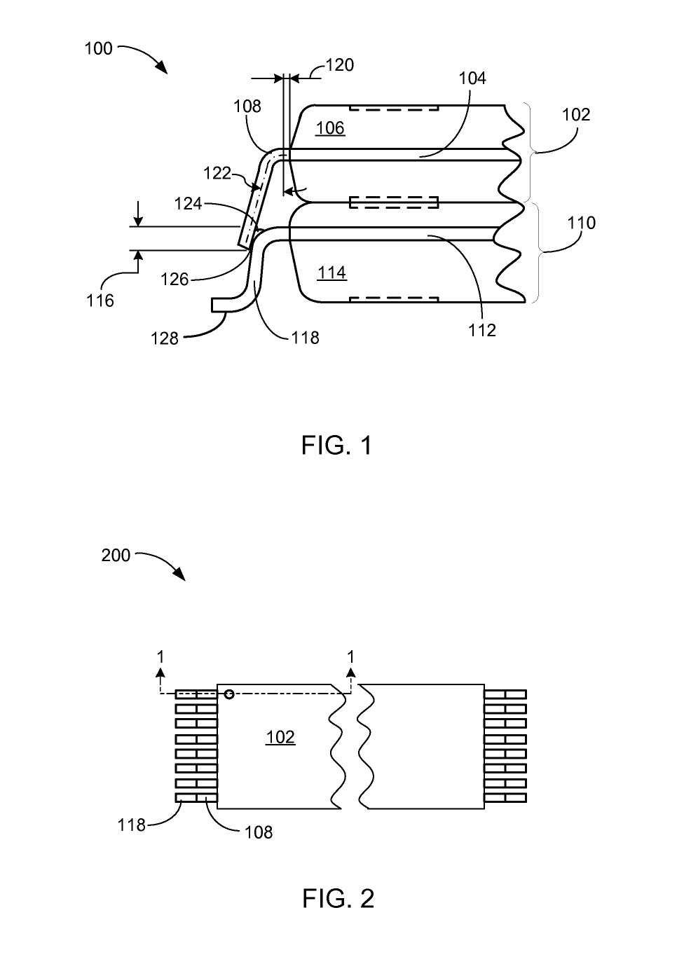

Referring now to FIG. 1, therein is shown a cross-sectional view of an integrated circuit package stacking system 100 in a first embodiment of the present invention. The cross-sectional view of the integrated circuit package stacking system 100 depicts a top package 102, such as a thin small-outline package (TSOP) having a centered parting line (CPL) as shown by the position of a top lead 104 centered within a top package body 106.

The top lead 104 may be formed of a metal, such as aluminum (Al), nickel (Ni), copper (Cu), or an alloy of metals. The top lead 104 may be a portion of a lead frame (not shown) encapsulated within the top package body 106 with top connection leads 108 extending beyond the top package body 106.

The top connection leads 108 may be re-shaped from an original configuration in order to facilitate coupling to a bottom package 110. The top package 102 is mounted over the bottom package 110, such as a TSOP having an off-centered parting line (OCPL) as shown by the position of a bottom lead 112 off-set from center within a bottom package body 114. It is understood that the bottom lead 112 may be a portion of a lead frame (not shown).

The top connection leads 108 of the top package 102 have been re-shaped from their original configuration to extend the reach of the top connection leads 108 in order to allow a lead overlap 116 having a sufficient margin. The reformed configuration of the top connection leads 108 also rests completely on bottom connection leads 118 of the bottom package 110.

A lead bending tools (not shown) may be part of a “back-end” process that finishes the manufactured packages prior to shipping. This configuration allows the sharing of back-end lead forming tools in the standard lead forming manufacturing flow.

The lead forming tool may start the re-shaped bend of the top connection lead 108 at a lead bend distance 120 of substantially 0.040 mm from the top package body 106. This may be compared to a prior art package that may start the bend of the top connection leads 108 at a normal distance (not shown) of substantially 0.093 mm form the top package body 106. This configuration is substantially similar to the formation of the bottom connection leads 118 of the bottom package 110.

A bend angle 122 of the top connection leads 108 may have a range of substantially 11° to 15°, whereas the angle of a prior art lead may be substantially 10°. This re-shaping of the top connection leads 108 may provide an increase in manufacturing yield by assuring the lead overlap 116 to be in the range of 0.23 mm to 0.24 mm.

A conductive adhesive 124, such as a solder or conductive epoxy, may be applied at a contact area 126 between the top connection leads 108 and the bottom connection leads 118. The contact area 126 may be substantially similar to the lead overlap 116.

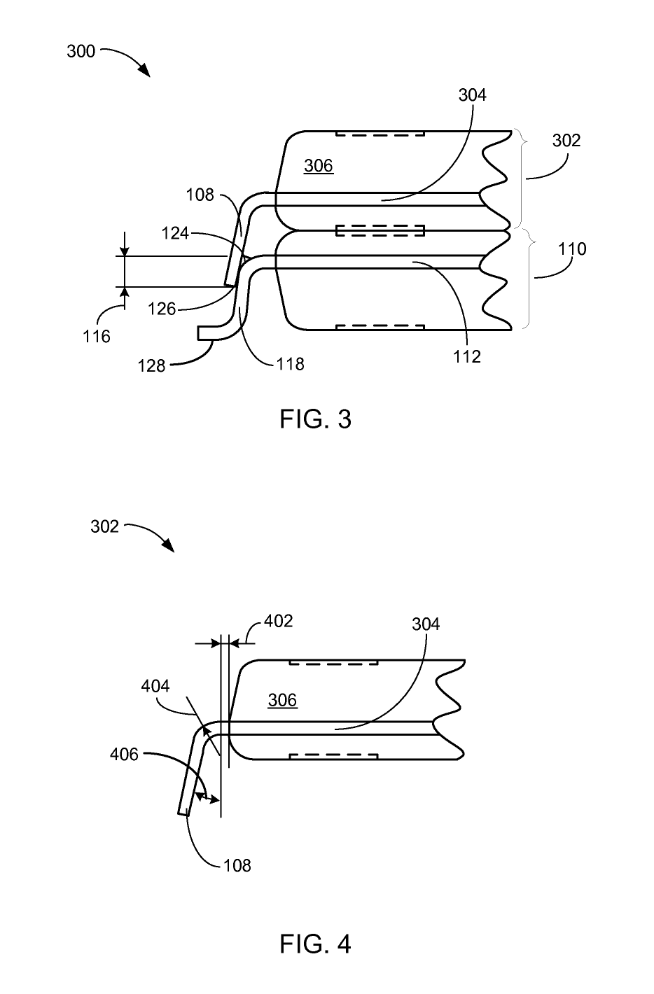

A coplanar contact 128 may be formed at or near the end of the bottom connection leads 118 for attachment to the next level system (not shown). It is understood that only a single example of the coplanar contact 128 is shown as an example, which is coplanar with similar surfaces on the rest of the bottom connection leads 118 that are not shown in the cross-section of FIG. 3.

It has been discovered that the top connection leads 108 may be reformed using the same back-end tooling that forms the bottom connection leads 118. By starting the bend closer to the top package body 106, increasing the bend angle 122 slightly, and maintaining the straight lead after the initial bend, the lead overlap 116 may be assured.

This invention provides a reliable manufacturing process for providing system level enhancements, such as increasing memory capacity of a system, without lengthy integrated circuit development. The present invention also provides a low cost and rapid solution for system architecture changes. It is further understood that the top package 102 and the bottom package 110 may contain an integrated circuit die (not shown) mounted on a lead frame (not shown).

Referring now to FIG. 2, therein is shown a top view of a package-on-package stack 200 utilizing thin small-outline packages (TSOP). The top view of the package-on-package stack 200 shows the top package 102 having the top connection leads 108 reformed and coupled to the bottom connection leads 118.

A section line 1-1 shows the position and direction of view of FIG. 1. While the section line 1-1 only shows a segment of the package-on-package stack 200, the formation of the top connection leads 108 and the bottom connection leads 118 are characteristic of the entirety of the package-on-package stack 200.

The top package 102 may be tested prior to lead reforming to assure a good manufacturing yield after assembly in the package-on-package stack 200. In certain applications the top package 102 may be formed from a package that was previously formed to be the bottom package 110, of FIG. 1, having the prior art configuration of the bottom connection leads 118.

In these cases, after assembling the package-on-package stack 200, an abbreviated electrical test module such as an operating system test may be performed in order to verify the assembly. In the instance where memory chips are to be stacked in the package-on-package stack 200, reading memory capacity may be sufficient to verify the assembly.

Referring now to FIG. 3, therein is shown a cross-sectional view of an integrated circuit package stacking system 300 in a second embodiment of the present invention. The cross-sectional view of the integrated circuit package stacking system 300 depicts a top package 302 formed of an inverted off-center parting line (OCPL) package mounted on the bottom package 110.

In this embodiment of the present invention, the top package 302 is of a similar package type to the bottom package 110. The top package 302 is formed with a top lead 304 in the off-center parting line position with a top package body 306 in an inverted position as compared to the bottom package 110. It is understood that the top lead 304 may be a portion of a lead frame (not shown).

The top connection leads 108 have been reformed to extend in a direction that is opposite to the bottom connection leads 118. By then inverting the top package 302 and placing it on the bottom package 110, the top connection leads 108 may overlap and contact the bottom connection leads 118.

The top connection leads 108, of the top package 302, provide a significant increase in the lead overlap 116 as compared to the first embodiment. The lead overlap 116, for this second embodiment of the present invention, may provide and increased contact area on the bottom connection leads 118 for a reliable connection as well.

The lead overlap 116 for the second embodiment may be in the range of 0.41 mm to 0.42 mm. The conductive adhesive 124, such as a solder or conductive epoxy, may be applied at the contact area 126 between the top connection leads 108 and the bottom connection leads 118.

The contact area 126 may be substantially similar to the lead overlap 116. This range of the lead overlap 116 may provide more of the contact area 126 and a highly reliable signal connection between the top connection leads 108 and the bottom connection leads 118.

The coplanar contact 128 may be formed at or near the end of the bottom connection leads 118 for attachment to the next level system (not shown). It is understood that only a single example of the coplanar contact 128 is shown as an example, which is coplanar with similar surfaces on the rest of the bottom connection leads 118 that are not shown in the cross-section of FIG. 3.

This configuration may require a special bonding pattern, within the top package 302, for matching signal position of the bottom package 110 or integrated circuit die of the top package may be installed in an inverted position in the top package 302. This configuration may still share the back-end lead forming tools in the standard lead forming manufacturing flow. It is further understood that the top package 302 and the bottom package 110 may contain an integrated circuit die (not shown) mounted on a lead frame (not shown).

Referring now to FIG. 4, therein is shown a cross-sectional view of the top package 302 having worst case manufacturing tolerances. The cross-sectional view of the top package 302 depicts the top lead 304 formed in an off-center parting line position within the top package body 306.

The top connection leads 108 may be re-formed to provide a lead bend distance 402 in the range of 0.04 mm to 0.093 mm. In this case the 0.093 mm is the worst case as it will extend the top connection lead 108 away from the intended position on the contact area 126.

A bend radius 404 may be less than or equal to 0.31 mm. The 0.31 mm of the bend radius 404 is equivalent to the bottom connection leads 118, of FIG. 1, of the bottom package 110, of FIG. 1, as they were originally formed.

A bend angle 406 may be between 11° and 15° as measured from the end of the lead bend distance 402 to the inner surface of the top connection leads 108. While the worst case bend angle of 15° extends the reach of the top connection lead 108, the substantial length of the lead overlap 116, of FIG. 1 provides a highly reliable connection between the top connection leads 108 and the bottom connection leads 118.

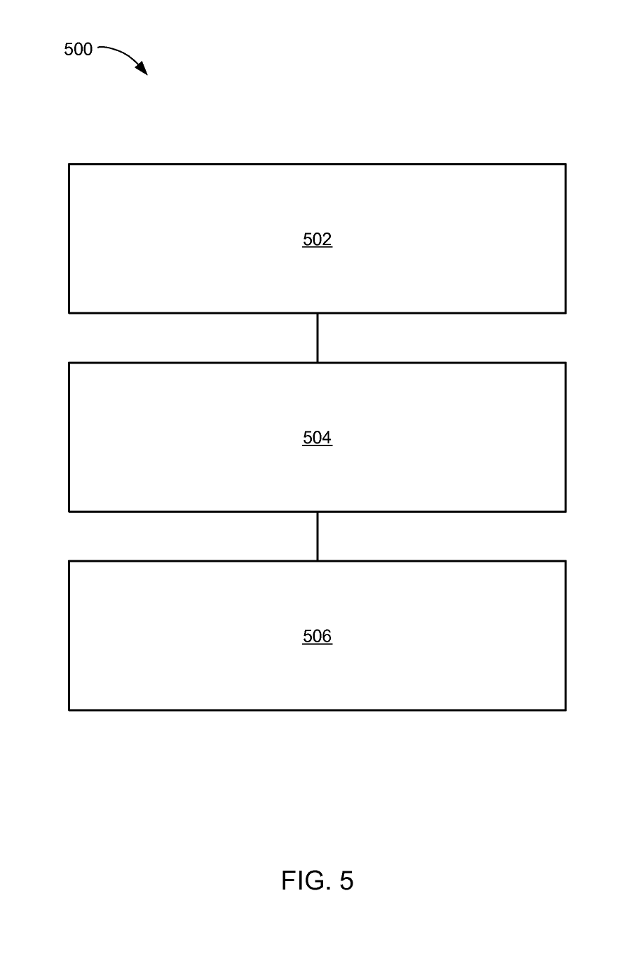

Referring now to FIG. 5, therein is shown a flow chart of a method 500 of manufacture of the integrated circuit package stacking system 100 in a further embodiment of the present invention. The method 500 includes: providing a bottom package including: providing a first lead frame, forming a bottom package body having the first lead frame in an off-centered parting line position, and forming bottom connection leads of the first lead frame for providing coplanar contacts at an end of the bottom connection leads in a block 502; mounting a top package on the bottom package including: providing a second lead frame, forming a top package body on the second lead frame, and reforming top connection leads of the second lead frame for over-lapping contact areas on the bottom connection leads of the bottom package in a block 504; and applying a conductive adhesive on the contact areas for electrically connecting the top connection leads and the bottom connection leads in a block 506.

The resulting method, process, apparatus, device, product, and/or system is straightforward, cost-effective, uncomplicated, highly versatile, accurate, sensitive, and effective, and can be implemented by adapting known components for ready, efficient, and economical manufacturing, application, and utilization.

Another important aspect of the present invention is that it valuably supports and services the historical trend of reducing costs, simplifying systems, and increasing performance.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit package stacking system comprising:
providing a bottom package including:
providing a first lead frame,
forming a bottom package body having the first lead frame in an off-centered parting line position, and
forming bottom connection leads of the first lead frame for providing coplanar contacts at an end of the bottom connection leads;
mounting a top package on the bottom package including:
providing a second lead frame,
forming a top package body on the second lead frame, and
reforming top connection leads of the second lead frame for over-lapping contact areas on the bottom connection leads of the bottom package; and
applying a conductive adhesive on the contact areas for electrically connecting the top connection leads and the bottom connection leads.

2. The method of claim 1 wherein mounting the top package includes mounting a center parting line package.

3. The method of claim 1 wherein mounting the top package includes mounting an off-center parting line package.

4. The method of claim 1 wherein mounting the top package on the bottom package includes mounting the top package body directly on the bottom package body.

5. The method of claim 1 further comprising forming a lead overlap between the top connection leads and the bottom connection leads.

6. A method of manufacture of an integrated circuit package stacking system comprising:
providing a bottom package including:
providing a first lead frame having bottom leads,
forming a bottom package body having the first lead frame in an off-centered parting line position including molding an epoxy molding compound on the bottom leads, and
forming bottom connection leads of the first lead frame for providing coplanar contacts at an end of the bottom connection leads;
mounting a top package on the bottom package including:
providing a second lead frame having top leads,
forming a top package body on the second lead frame including molding the epoxy molding compound on the top leads, and
reforming top connection leads of the second lead frame for over-lapping contact areas on the bottom connection leads of the bottom package; and
applying a conductive adhesive on the contact areas for electrically connecting the top connection leads and the bottom connection leads.

7. The method of claim 6 wherein mounting the top package includes mounting a center parting line package further comprising providing a lead bend distance of substantially 0.040 mm.

8. The method of claim 6 wherein mounting the top package includes mounting an off-center parting line package further comprising providing a lead bend distance in the range of 0.04 mm and 0.093 mm.

9. The method of claim 6 further comprising forming a bend angle, in the top connection leads, with a range of between 11° and 15°.

10. The method of claim 6 further comprising forming a lead overlap between the top connection leads and the bottom connection leads wherein forming the lead overlap is in the range of 0.23 mm and 0.42 mm.

11. An integrated circuit package stacking system comprising:
a bottom package includes:
a first lead frame,
a bottom package body, formed on the first lead frame, having the first lead frame in an off-centered parting line position, and
bottom connection leads formed of the first lead frame having coplanar contacts at an end of the bottom connection leads;
a top package mounted on the bottom package includes:
a second lead frame,
a top package body molded on the second lead frame, and
top connection leads formed of the second lead frame with contact areas on the bottom connection leads of the bottom package overlapped by the top connection leads; and
a conductive adhesive on the contact areas for electrically connecting the top connection leads and the bottom connection leads.

12. The system of claim 11 wherein the top package mounted includes a center parting line package mounted on the bottom package.

13. The system of claim 11 wherein the top package mounted includes an off-center parting line package mounted on the bottom package.

14. The system of claim 11 wherein the top package on the bottom package includes the top package body directly on the bottom package body.

15. The system of claim 11 further comprising a lead overlap between the top connection leads and the bottom connection leads.

16. The system of claim 11 further comprising:
bottom leads in the first lead frame;
an epoxy molding compound molded on the bottom leads forms the bottom package body;
top leads in the second lead frame; and
the epoxy molding compound molded on the top leads forms the top package body.

17. The system of claim 16 wherein the top package mounted includes a center parting line package mounted on the bottom package further comprising a lead bend distance of substantially 0.040 mm from the top package body.

18. The system of claim 16 wherein the top package mounted includes an off-center parting line package mounted on the bottom package further comprising a lead bend distance in the range of 0.040 mm to 0.093 mm from the top package body.

19. The system of claim 16 further comprising a bend angle, formed in the top connection leads, with a range of between 11° and 15°.

20. The system of claim 16 further comprising a lead overlap between the top connection leads and the bottom connection leads wherein the lead overlap is in the range of 0.23 mm and 0.42 mm.
